(19) United States
(12) Patent Application Publication
(10) Pub. No.: US 2012/0295420 A1
(43) Pub. Date: Nov. 22, 2012

(54) SEMICONDUCTOR DEVICES WITH REDUCED STI TOPOGRAPHY BY USING CHEMICAL OXIDE REMOVAL

(75) Inventors: Rohit Pal, Dresden (DE); Stephan-Detlef Kronholz, Dresden (DE)

(73) Assignee: GLOBALFOUNDRIES INC., Grand Cayman (KY)

(21) Appl. No.: 13/470,906

(22) Filed: May 14, 2012

(30) Foreign Application Priority Data
May 20, 2011 (DE) 10 2011 076 185.3

(51) Int. Cl. H01L 21/20; H01L 21/283

(52) U.S. Cl. 438/478; 438/585; 257/E21.09; 257/E21.19

(57) ABSTRACT

A thermal oxide may be removed in semiconductor devices prior to performing complex manufacturing processes, such as forming sophisticated gate electrode structures, by using a gaseous process atmosphere instead of a wet chemical etch process, wherein the masking of specific device regions may be accomplished on the basis of a resist mask.

### BACKGROUND OF THE INVENTION

1. Field of the Invention

Generally, the present disclosure relates to advanced integrated circuits and manufacturing techniques and, more particularly, to advanced transistors with gate lengths of 50 nm or less.

2. Description of the Related Art

The fabrication of advanced integrated circuits, such as CPUs, storage devices, ASICs (application specific integrated circuits) and the like, requires a large number of circuit elements to be formed on a given chip area according to a specified circuit layout, wherein field effect transistors represent one important type of circuit element that substantially determines performance of the integrated circuits. Generally, a plurality of process technologies are currently practiced, wherein, for many types of complex circuitry including field effect transistors, CMOS technology is one of the most promising approaches due to the superior characteristics in view of operating speed and/or power consumption and/or cost efficiency. During the fabrication of complex integrated circuits using, for instance, CMOS technology, millions of transistors, i.e., N-channel transistors and P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Hence, the scaling of the channel length, and associated therewith the reduction of channel resistivity and reduction of gate resistivity, is a dominant design criterion for accomplishing an increase in the operating speed of the integrated circuits.

In most recent complex semiconductor devices, such as CPUs, GPUs and the like, which are typically formed on the basis of silicon material due to its superior availability and the well-established process techniques and materials, such as silicon dioxide, silicon nitride and the like, a gate length of 50 nm and significantly less is used in advanced transistors in order to meet the requirements in terms of performance and packing density. To this end, sophisticated lithography and etch techniques are typically required which, however, may sensitively depend on the overall surface topography of the semiconductor devices. For example, the very advanced lithography techniques may strongly depend on the characteristics of resist materials, which may have to be applied with a reduced thickness in order to comply with the requirements for uniform exposure and photochemical efficiency, a corresponding reduced thickness of the resist materials, however, typically requires sophisticated hard mask approaches in order to pattern underlying material layers, such as gate layer stacks and the like. Furthermore, due to the sophisticated lithography tools used in patterning sophisticated device structures, a variation in the surface topography, which may result in exposure variations due to a reduced depth of focus in sophisticated exposure tools, even minute variations in the surface topography may increasingly affect the further processing, for instance, the patterning of gate electrode structures or other three-dimensional sophisticated transistors requiring device features with critical dimensions of 50 nm and less. One mechanism that increasingly contributes to structural variations upon patterning complex device features has been identified as pronounced material loss in isolation regions, which are typically provided in the form of shallow trench isolations or other sophisticated field isolation regions in order to appropriately laterally delineate active regions. For example, STI (shallow trench isolation) structures are frequently used in complex semiconductor devices, which are typically fabricated on the basis of lithography and etch techniques in order to provide appropriately dimensioned trenches in the semiconductor material. Thereafter, the trenches are filled on the basis of a silicon dioxide material that is deposited by using well-established deposition techniques. During the further processing, however, frequently, thermal silicon dioxide layers are formed on the exposed active regions and have to be removed, which is typically accomplished on the basis of well-established and highly efficient wet chemical etch chemistries, for instance provided on the basis of diluted hydrofluoric acid (HF). Although diluted Hf is a very efficient cleaning and etch recipe for silicon dioxide material and surface contaminations, it turns out, however, that the etch attack on field oxide regions typically results in a pronounced surface topography in an early manufacturing stage, i.e., prior to or upon patterning complex device features, such as sophisticated gate electrode structures, which may then increasingly contribute to device variations, as discussed above.

With reference to FIGS. 1a-1e, process sequences for removing a thermal oxide material in sophisticated manufacturing techniques will now be described in more detail in order to more clearly demonstrate possible sources of creating non-uniformities during the fabrication of sophisticated semiconductor devices.

FIG. 1a schematically illustrates a cross-sectional view of a semiconductor device 100 in an early manufacturing stage. As illustrated, the device 100 comprises a substrate 101, which is typically provided in the form of a semiconductor material, such as a silicon material and the like. A semiconductor layer 102, such as a silicon layer, is formed above the substrate 101 and is typically provided, in an initial state, as a continuous semiconductor material, which is subsequently divided into a plurality of device regions or semiconductor regions, such as regions 102A, 102B. The regions 102A, 102B may thus be considered as active regions in which one or more semiconductor-based circuit elements, such as field effect transistors, are to be formed. As discussed above, an appropriate lateral delineation of the semiconductor regions 102A, 102B is typically achieved by providing an isolation structure or region 102C, for instance in the form of a shallow trench isolation, as explained before. Furthermore, in this manufacturing stage, a silicon dioxide layer 103 is formed in or on the semiconductor regions 102A, 102B, indicated by 103A, 103B, respectively, wherein the layer 103 may represent a material layer that may have been used during the further processing or which may have formed in the form of a native oxide and the like, and which may have to be removed prior to continuing processing by applying complex process techniques, for instance involving sophisticated lithography and patterning processes.

The device 100 is typically formed on the basis of the following process strategy. As discussed above, the semiconductor layer 102 is typically divided into appropriately sized semiconductor regions, such as the regions 102A, 102B, by forming the isolation structure 102C, which typically involves lithography and etch techniques for forming trenches, which are subsequently filled with an appropriate dielectric material, such as silicon dioxide, possibly in combination with additional oxidation and anneal processes, for instance for densifying the deposited oxide material. It should be appreciated that, frequently, a process of forming the isolation regions 102C may be preceded by forming an oxide layer on the semiconductor layer 102, possibly in combination with an additional hard mask material, such as silicon nitride, which may then be used throughout the entire process sequence for completing the structure 102C. Consequently, after removing any excess material, the layer 103 may represent the residue of a previously formed silicon dioxide material, which may have a high density and thus have an increased etch resistivity due to its thermally grown nature compared to the mostly deposited silicon dioxide material in the isolation region 102C. The thermal oxide layer 103 is typically removed by applying a wet chemical etch process 104 on the basis of diluted HF, which, however, also removes material of the isolation region 102C, wherein typically the removal rate is 1.5 times to two times greater than the removal rate of the thermal oxide material in the layer 103.

FIG. 1b schematically illustrates the device 100 after the removal of the thermal oxide layer 103 (FIG. 1a), thereby causing a significant loss of material in the isolation structure 102C, which in turn results in a pronounced degree of recessing with respect to the semiconductor regions 102A, 102B, as indicated by 102R. For example, the recess 102R may be in the range of twenty to several tenths of nanometers, which may significantly affect the further processing, for instance when forming sophisticated gate electrode structures 160A, 160B having a gate length 160L in the range of 50 nm and significantly less. Since any non-uniformities introduced in the resulting semiconductor devices upon, for instance, forming the complex gate electrode structures 160A, 160B are no longer acceptable upon further scaling the semiconductor devices, new strategies have been developed in order to efficiently remove thermal oxide material, while reducing the degree of material loss and thus the degree of surface topography prior to performing complex manufacturing techniques.

FIG. 1c schematically illustrates the device 100 in a similar state as the device 100 shown in FIG. 1a, in which the thermal oxide layer 103 is to be removed from the semiconductor regions 102A, 102B. In this case, however, rather than applying a wet chemical etch chemistry on the basis of HF, a gaseous etch ambient 105A is established by using ammonia (NH₃) and gaseous hydrogen fluoride (HF), possibly in combination with additional carrier gases, such as noble gases, nitrogen and the like. It has been recognized that the application of this gaseous etch ambient may result in a pronounced material modification of exposed oxide materials, wherein, however, a significantly reduced discrepancy between deposited oxide and thermal oxide is achieved. For example, a selectivity of approximately 1:1 for deposited and thermal oxide may be achieved, while by even further adapting the process conditions, an even increased removal rate may be obtained for thermal oxide.

FIG. 1d schematically illustrates the device 100 after the process step 105A of FIG. 1c, during which exposed oxide materials are “converted” into a sacrificial material, which may basically be comprised of a complex compound including ammonium and silicon hexafluoride. As shown, a sacrificial layer 103S may be formed on the semiconductor regions 102A, 102B, while an upper portion of the exposed isolation region 102C is converted into a sacrificial layer 102S. Since the “etch rate” or “conversion rate” is similar for the materials 103 and 102C (FIG. 1c), also the thickness of the sacrificial layers 103S, 102S may be comparable, wherein the ratio may even be adjusted by adjusting the corresponding selectivity, as discussed above.

FIG. 1e schematically illustrates the device 100 in a further step of the removal process for thermal oxide material, as indicated by 105B. In this process step, the device 100 is typically heated to temperatures well above 200° C., thereby initiating the sublimation of the sacrificial layers 103S, 102S in order to actually remove the thermal oxide material. As discussed above, since the actual removal rates for the materials 103 (FIGS. 1c) and 102c may be comparable or the removal rate for the material 102C may even be less, a resulting degree of recessing, as indicated by 102R, is significantly reduced compared to the situation as described with reference to FIG. 1b.

Frequently, a thermal oxide material has to be removed selectively from certain device areas in order to perform complex manufacturing techniques, which may be accomplished on the basis of the above-described process technique by forming an appropriate hard mask layer.

FIG. 1f schematically illustrates the semiconductor device 100 in a corresponding process stage in which the thermal oxide layer 103 is to be removed selectively from above the semiconductor region 102A, while the semiconductor region 102B has to remain covered by the layer 103. To this end, a silicon nitride layer 106 is typically formed above the regions 102A, 102B and is subsequently patterned by using a resist material 107 on the basis of well-established lithography techniques. After patterning the hard mask layer 106, the resist mask 107 is removed and the further processing is continued, as described above with reference to FIGS. 1c-1e, in order to remove the exposed portion of the layer 103 while the hard mask material 106 may appropriately mask the material 103 above the semiconductor region 102B and may withstand the elevated temperatures that are used to remove the sacrificial material formed from the exposed layer 103, as discussed above. Typically, the hard mask layer 106 is then removed prior to performing any required process steps.

For example, a selective exposure of the semiconductor material of some active regions may be required in complex process techniques in which a threshold adjusting semiconductor alloy is to be formed on the active region of certain transistors, while other active regions may not require the incorporation of a dedicated threshold voltage adjusting semiconductor material. In other cases, any other selective treatment of some active regions has to be applied, wherein the remaining layer 103 on the semiconductor region 102B may act as an efficient hard mask material, such as a growth mask, when performing a selective epitaxial growth process, for instance for providing a specific semiconductor material on the exposed semiconductor region 102A.

Generally, the above-described process sequence for removing a thermal oxide material on the basis of a two-step removal process in a gaseous ambient, in combination with a heat treatment at elevated temperatures of at least 200° C., may represent a very efficient process strategy in order to reduce the resulting surface topography in an early manufacturing stage, wherein, however, a selective removal of a thermal oxide material requires the deposition, the patterning and at a later stage the removal of a specific hard mask removal, such as a silicon nitride material, which thus contributes to complexity of the overall process flow.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques in which a thermal oxide, such as a silicon dioxide material, may be efficiently removed on the basis of a gaseous ambient in order to form, in a first step, a highly volatile sacrificial layer, which may be subsequently removed on the basis of process conditions that are compatible with the presence of a resist material. In this manner, a thermal oxide material may be selectively removed from certain device areas on the basis of a resist mask, thereby avoiding the deposition, patterning and removal of a dedicated hard mask material. In some illustrative embodiments disclosed herein, the selective removal of a thermal oxide material may be performed in the context of providing a dedicated semiconductor material selectively in some active region, for instance in the form of a threshold voltage adjusting semiconductor alloy, which may result in a reduced surface topography, thereby enhancing the process conditions during the further processing of the device, for instance upon forming sophisticated gate electrode structures.

One illustrative method disclosed herein comprises providing a thermal oxide layer in a first semiconductor region and a second semiconductor region of a semiconductor device, wherein the first and second semiconductor regions are laterally delineated by an isolation region. The method further comprises forming a resist mask above the second semiconductor region and above a portion of the isolation region so as to expose the thermal oxide layer in the first semiconductor region. Furthermore, the method comprises removing the thermal oxide layer in the first semiconductor region by using a gaseous process ambient that comprises ammonia (NH₃) and hydrogen fluoride (HF) and by using the resist mask as a removal mask.

A further illustrative method disclosed herein comprises forming a resist mask above a semiconductor device so as to expose a first device region and cover a second device region, wherein at least the first device region comprises a thermal oxide layer. The method further comprises forming a sacrificial layer from the thermal oxide layer in the first device region by establishing a gaseous process ambient that comprises ammonia and hydrogen fluoride in the presence of the resist mask. Moreover, the method comprises removing the sacrificial layer and the resist mask by performing a wet chemical etch process.

A still further illustrative method disclosed herein comprises forming a resist mask above a semiconductor device so as to expose a first device region and cover a second device region, wherein at least the first device region comprises a thermal oxide layer. Moreover, the method comprises forming a sacrificial layer from the thermal oxide layer in the first device region by establishing a gaseous process ambient that comprises ammonia and hydrogen fluoride in the presence of the resist mask. Furthermore, the method comprises removing the sacrificial layer in the presence of the resist mask by performing a heat treatment at a temperature of 175° C. or less.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a sophisticated semiconductor device upon removing a thermal oxide layer on the basis of a wet chemical etch chemistry comprising HF;

FIGS. 1c-1f schematically illustrate the conventional semiconductor device upon removing a thermal oxide material by using a gaseous process ambient and a high temperature treatment in a non-masked process sequence (FIGS. 1c-1e) and a masked process sequence (FIG. 10 according to conventional strategies;

FIGS. 2a-2e schematically illustrate cross-sectional views of a semiconductor device during various manufacturing stages in removing a thermal oxide layer on the basis of a gaseous process ambient and process conditions which are compatible with the presence of a resist material, according to illustrative embodiments; and

FIGS. 3a-3h schematically illustrate cross-sectional views of a semiconductor device during various manufacturing stages when removing a thermal oxide material with reduced material loss in isolation regions during a complex manufacturing sequence for forming sophisticated gate electrode structures in combination with a threshold voltage adjusting semiconductor alloy, according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

According to the principles disclosed herein, the surface topography of semiconductor devices after the removal of a thermal oxide material and prior to performing complex manufacturing sequences, such as forming sophisticated gate electrode structures, which may include selective deposition of a threshold voltage adjusting semiconductor alloy, such as a silicon/germanium alloy and the like, may be significantly improved compared to conventional strategies by using a gaseous process ambient for converting the thermal oxide material into a sacrificial material, which in turn may be removed on the basis of process conditions that may be compatible with the presence of a resist material. In this manner, a thermal oxide material may be selectively removed from certain device regions by using a resist mask without requiring additional processes for forming a hard mask material, patterning the same and removing the hard mask material in a later manufacturing stage. In some illustrative embodiments, the removal of the sacrificial material, which is basically a highly volatile nitrogen, hydrogen, silicon and fluorine-containing material complex, may be accomplished by applying process temperatures that are below the class transition temperature of the resist material, which is typically at approximately 175° C. Consequently, in these embodiments, a heat treatment may be applied on the basis of a process temperature that is 175° C. or less in order to avoid undue modification of the resist material, while at the same time efficiently removing the volatile material of the sacrificial layer. Thereafter, the resist material may still be removed on the basis of well-established removal techniques, for instance using wet chemical cleaning recipes, plasma assisted etch processes and the like.

In other illustrative embodiments disclosed herein, the sacrificial material may be formed in the presence of a resist mask, for instance in order to preserve a thermal oxide material in dedicated device areas, and subsequently the resist mask and the sacrificial layer may be removed in a wet chemical etch process, for instance using well-established chemicals such as sulfuric acid and hydrogen peroxide in combination (SPM) and the like, wherein the wet chemical removal process may be performed in a separate process environment compared to the process environment used for establishing the gaseous process ambient.

In some illustrative embodiments, the masked removal of a thermal oxide may be applied prior to forming sophisticated gate electrode structures, thereby achieving superior process flexibility in individually adjusting the characteristics of semiconductor regions or generally of device regions, while on the other hand the further processing may then be continued on the basis of a reduced surface topography. In some illustrative embodiments, the masked removal of a thermal oxide with reduced material loss in isolation regions may be advantageously applied to the formation of a threshold voltage adjusting semiconductor alloy in some active regions, while the remaining thermal oxide material may be used as an efficient hard mask material during the selective epitaxial growth process. Since, in a conventional process strategy, additional hard mask material deposition and patterning strategies may have to be applied, a significant reduction in overall process complexity may be achieved, while still a pronounced reduction of the resulting surface topography may be achieved prior to forming the complex gate electrode structures. For example, in sophisticated applications, the gate electrode structures may be provided on the basis of a high-k dielectric material in combination with metal-containing electrode materials, which may require a reliable encapsulation so as to preserve integrity of the sensitive gate materials. In this case, the patterning process itself, as well as the subsequent encapsulation of the resulting gate electrode structures, may be accomplished with significantly reduced non-uniformities due to the superior surface topography achieved by reducing the material loss in the isolation regions upon removing a thermal oxide material. Consequently, in these cases, overall transistor variability may be reduced, thereby contributing to increased overall yield caused by superior process robustness.

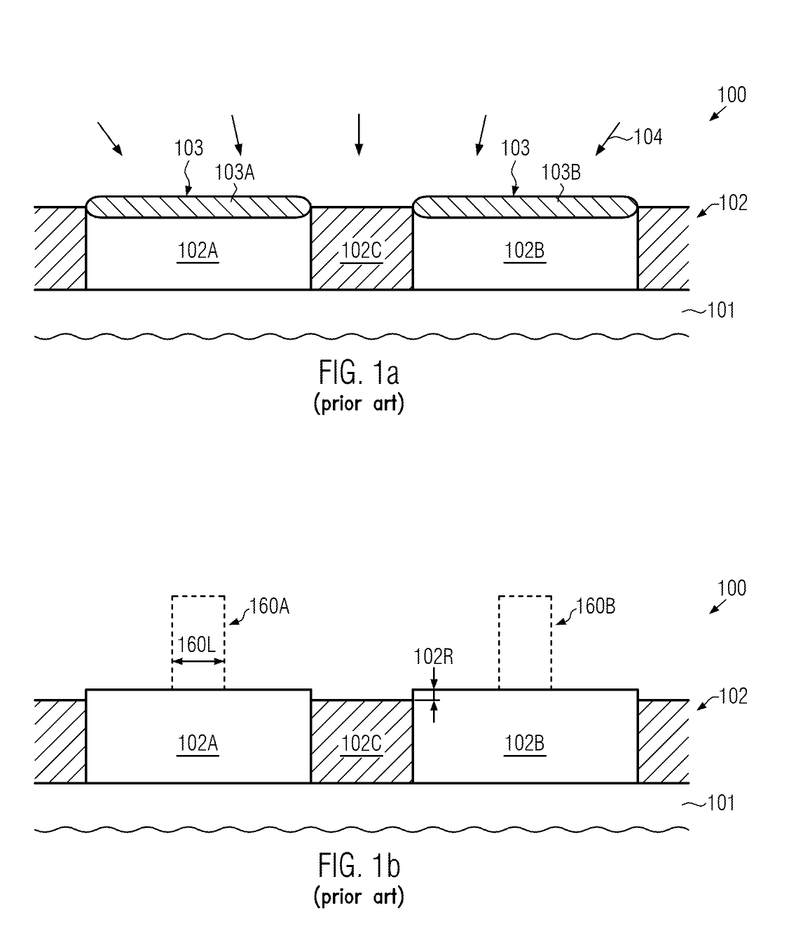

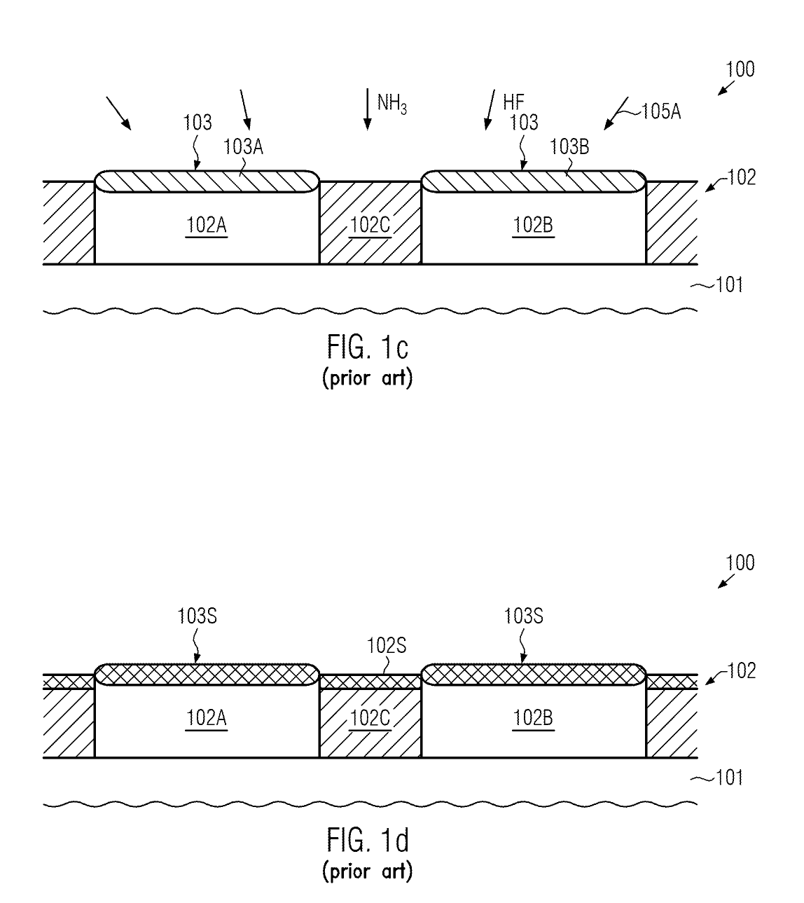

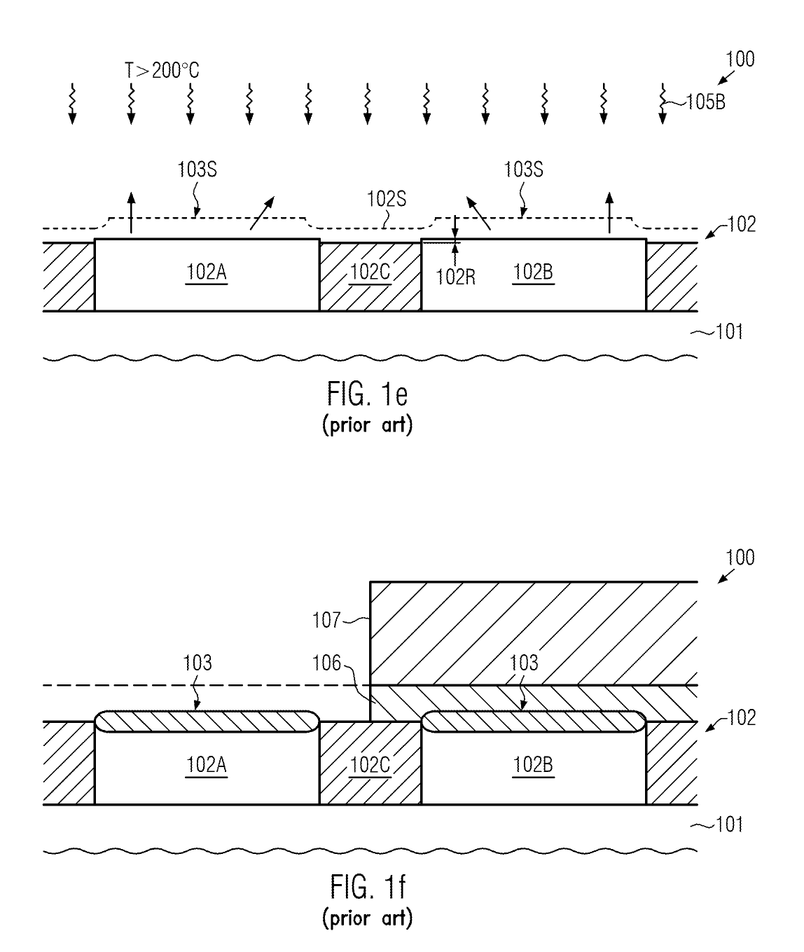

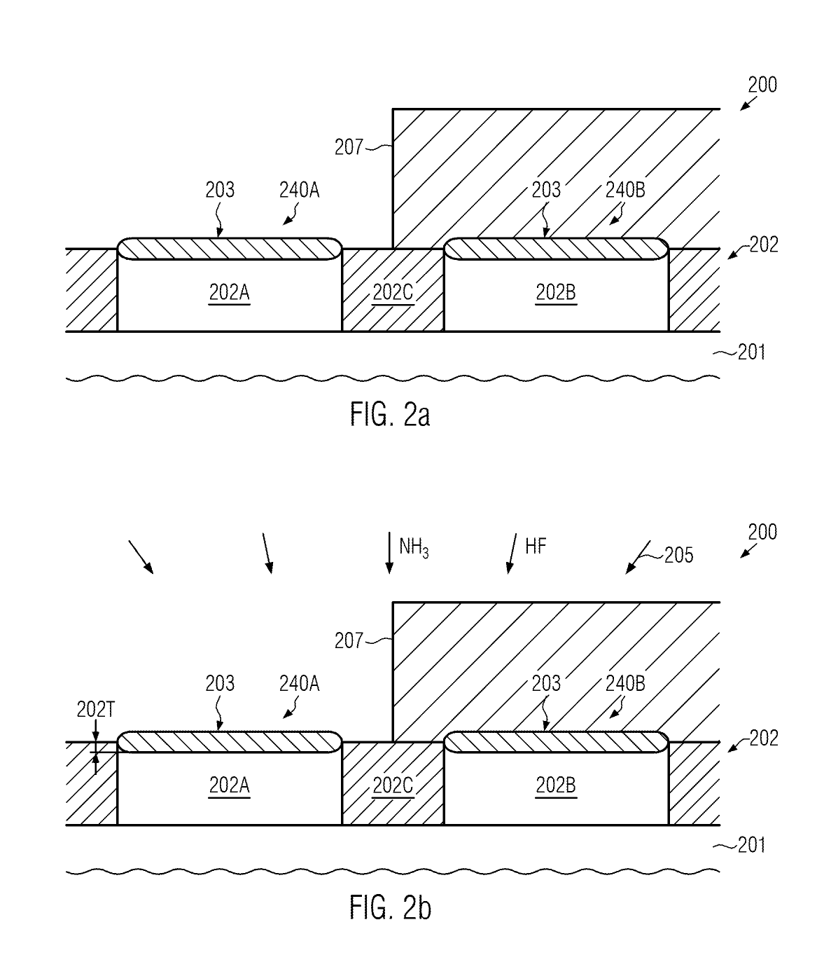

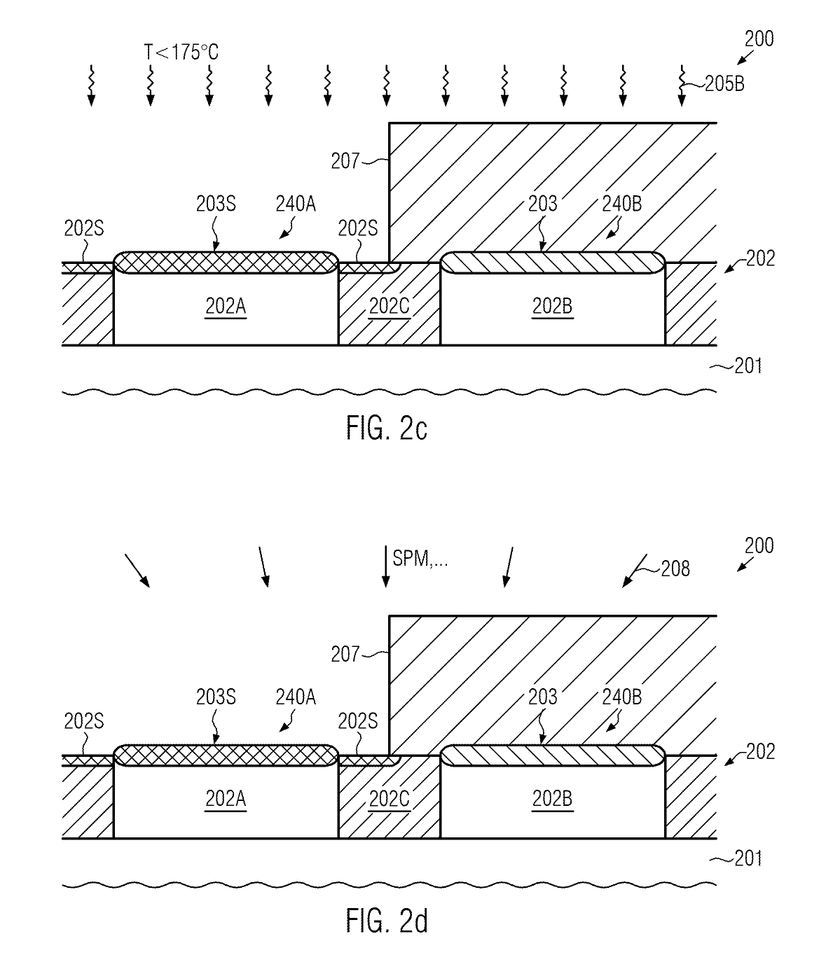

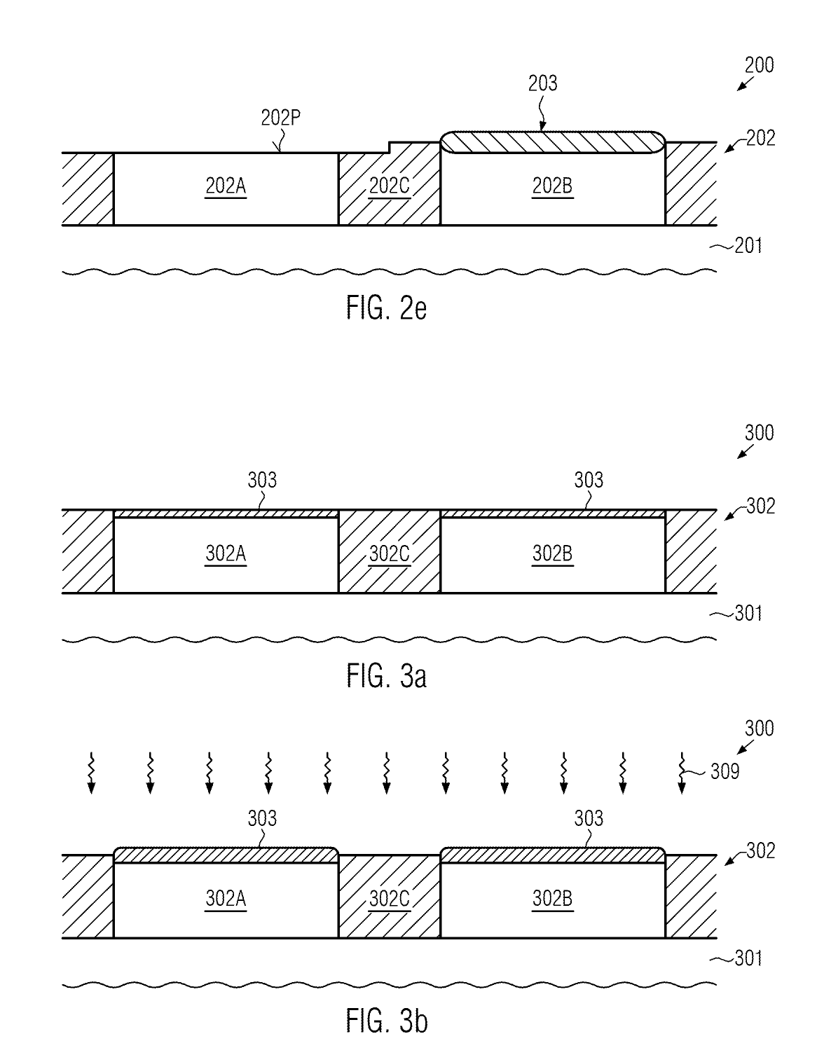

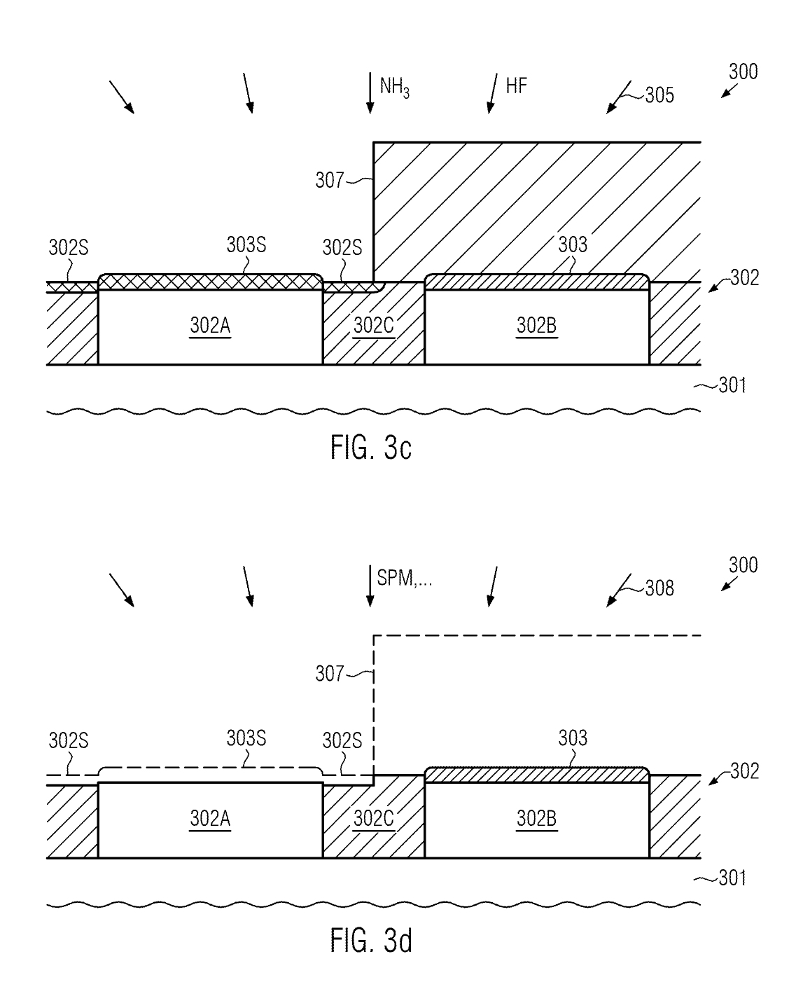

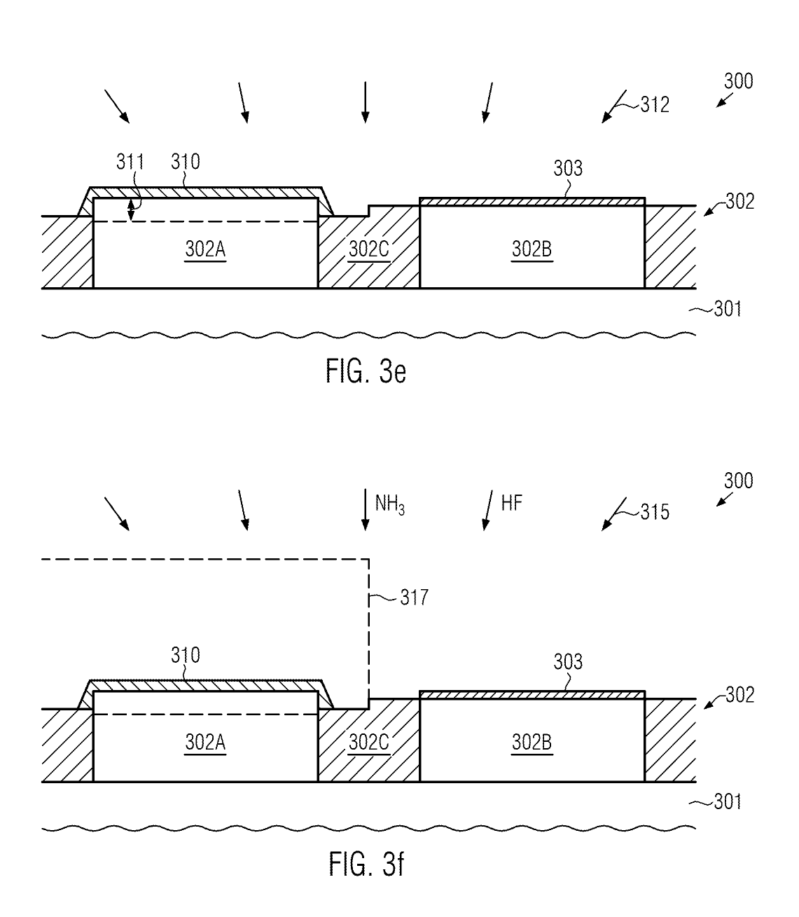

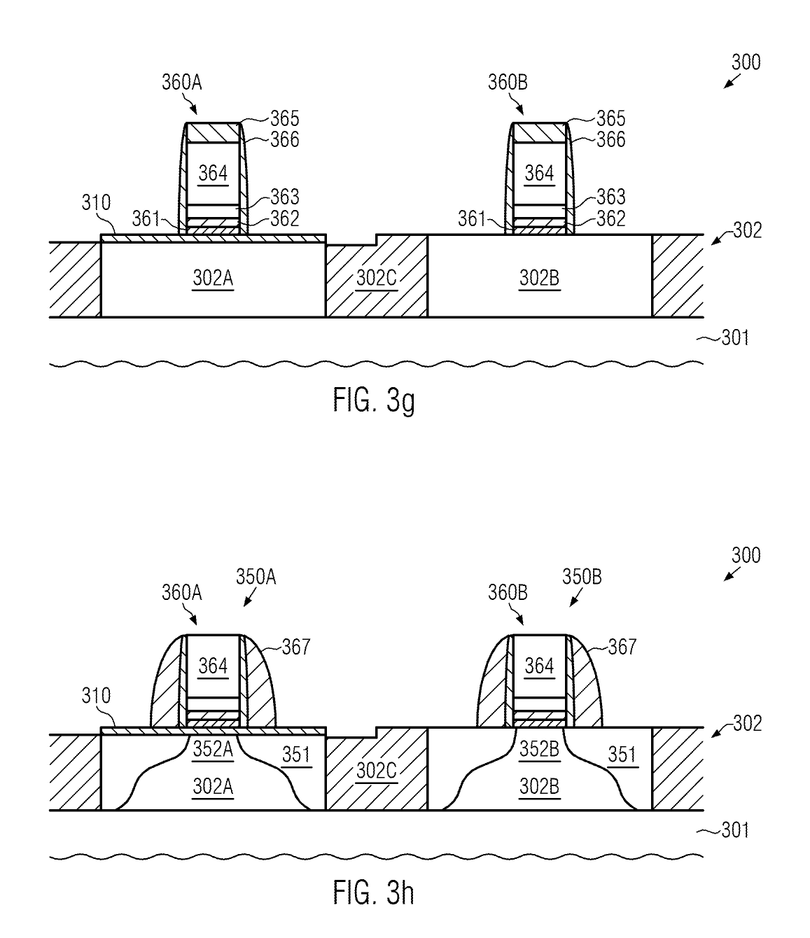

With reference to FIGS. 2a-2e and 3a-3h, further illustrative embodiments will now be described in more detail, wherein reference may also be made to FIGS. 1a-1f, if required.

FIG. 2a schematically illustrates a cross-sectional view of a semiconductor device 200, which may comprise a substrate 201 and a semiconductor layer 202. The semiconductor layer 202 may be laterally delineated into a plurality of device regions 240A, 240B which comprise or may represent semiconductor regions 202A, 202B, for instance in the form of active regions for transistor elements still to be formed. To this end, isolation regions 202C may be provided in any appropriate form, for instance in the form of shallow trench isolations, as is also previously discussed with reference to the semiconductor device 100. It should be appreciated that the semiconductor layer 202 may initially be provided in the form of any appropriate continuous semiconductor material, such as a silicon material, a silicon/germanium material and the like. Furthermore, in some cases, a buried insulating layer (not shown) may be formed directly below the semiconductor layer 202 if an SOI (silicon-on-insulator) architecture is to be considered. In other cases, the semiconductor layer 202 may directly connect to a crystalline material of the substrate 201, thereby forming a bulk configuration. Furthermore, in the manufacturing stage shown, a thermal oxide layer 203 may be formed in the semiconductor regions 202A, 202B, for instance in the form of a silicon dioxide material, wherein also a certain amount of other species, such as germanium, may be included in the oxide layer 203. Furthermore, a resist mask 207 may be formed so as to expose the device region 240A, i.e., the layer 203 formed in and on the semiconductor region 202A and a portion of the isolation structure 202C. On the other hand, the resist mask 207 covers the device region 240B, i.e., a portion of the isolation region 202C and the material 203 formed in the semiconductor region 202B.

The semiconductor device 200 as shown in FIG. 2a may be formed on the basis of any appropriate process strategy, as is, for instance, also described above with reference to the device 100. That is, the isolation region 202C may be formed on the basis of any well-established process strategy, as discussed above, followed by further processes, such as the incorporation of well dopant species into the regions 202A, 202B, which may include sophisticated implantation and masking techniques in order to provide a desired type of conductivity in the regions 202A, 202B. For example, the regions 202A, 202B may represent semiconductor regions of inverse conductivity type, for instance for forming P-channel transistors and N-channel transistors, respectively. The thermal oxide layer 203 may represent a residue of the preceding processing, as is also discussed above, or may have been formed in accordance with the overall process and device requirements. For example, a thickness of the thermal oxide layer 203 may be 4-20 nm in this manufacturing stage. The resist mask 207 may be formed on the basis of well-established lithography techniques. It should be appreciated that the resist mask 207 may act as a removal mask for selectively removing the thermal oxide material 203 from the semiconductor region 202A without requiring any additional hard mask material.

FIG. 2b schematically illustrates the semiconductor device 200 in a further advanced manufacturing stage in which a gaseous process ambient 205 may be established on the basis of ammonia (NH₃) and gaseous hydrofluoric acid (HF), which may be accomplished in any appropriate process chamber. To this end, these gaseous components may be provided with appropriate gas flow rates in a ratio of 4:1-1:4, for instance approximately 2:1 HF:NH₃, wherein generally any additional carrier gas, such as noble gases in the form of argon, helium and the like, or other inert gases such as nitrogen, may be incorporated into the gaseous ambient 205. For example, a pressure of approximately 1-20 mTorr may be established in the process ambient 205, wherein a process temperature may be well below the glass transition temperature of the resist material 207.

As discussed above with reference to the device 100, basically the process ambient 205 may result in a conversion of the oxide material in the layers 203 and in the isolation regions 202C with a rate that may be adjusted on the basis of parameters such as the ratio of gas flow rates and carrier gases. For example, a corresponding reaction rate in the region 202C and the layer 203 may be selected to be approximately the same, while even a reduced reaction rate in the region 202C may be selected compared to the reaction rate in the thermal oxide material 203. Consequently, a corresponding thickness 202T in the exposed portions of the isolation region 202C may be converted into an ammonium and silicon fluoride-containing sacrificial material layer.

FIG. 2c schematically illustrates the device 200 according to illustrative embodiments in which a heat treatment 205B may be applied at a process temperature of 175° C. and less in order to initiate the removal of sacrificial layers 202S, 203S, which have been formed in the previous step 205 of FIG. 2b. The heat treatment 205B may be performed in the same process environment as the process 205 of FIG. 2b, while, in other cases, a dedicated process chamber may be used for the heat treatment 205B.

It has been recognized that the application of temperatures below the class transition temperature of the resist material 207 may still be highly efficient in initiating a sublimation of the sacrificial material layers 202S, 203S, thereby enabling an efficient selective removal of thermal oxide from the semiconductor region 202A, without unduly contributing to a pronounced material loss in the isolation structure 202C and without unduly modifying the material of the resist mask 207, which may thus be efficiently removed in a later manufacturing stage.

FIG. 2d schematically illustrates the device 200 according to further illustrative embodiments in which the sacrificial layers 202S, 203S may be efficiently removed on the basis of a wet chemical etch process 208, which may be performed, for instance, on the basis of a mixture of sulfuric acid and hydrogen peroxide (SPM) and the like. To this end, the wet chemical process 208 may be performed in a dedicated process chamber, wherein, in some illustrative embodiments, concurrently the resist mask 207 may also be removed during the process 208. In other cases, the removal of the resist mask and of the sacrificial layers 202S, 203S may be performed in separate steps, wherein the mask 207 may be removed prior to or after the removal of the sacrificial layers 202S, 203S.

FIG. 2e schematically illustrates the device 200 after the removal of a thermal oxide and the removal of the resist mask 207 (FIGS. 2c, 2d). Consequently, a surface topography 202P with superior smoothness is obtained in the semiconductor region 202A with respect to the isolation structure 202C, while the semiconductor region 202B is still reliably covered by the thermal oxide layer 203. In this stage, further processes may be performed in accordance with the overall process and device requirements, for instance specifically adjusting characteristics of the semiconductor region 202A and the like, for example by providing a specific material layer thereon, as will also be described later on with reference to FIGS. 3a-3h. In a further advanced manufacturing stage, the layer 203 may also be removed from the semiconductor region 202B, which may also be accomplished on the basis of a gaseous process ambient as described above, wherein, if required, an additional resist mask may be applied so as to cover the region 202A when exposure to the respective process atmospheres is considered inappropriate. In this case, a similar process strategy may be applied, as described above. Thereafter, sophisticated device features, such as gate electrode structures, may be formed on the basis of sophisticated lithography and etch techniques, as is also described above with reference to the semiconductor device 100.

With reference to FIGS. 3a-3h, further illustrative embodiments will now be described in more detail, wherein dedicated semiconductor regions may receive a semiconductor material on the basis of a selective deposition process in which a thermal oxide material may be used as a hard mask material, thereby requiring the selective removal of the thermal oxide material from the dedicated semiconductor regions.

FIG. 3a schematically illustrates a semiconductor device 300 in an early manufacturing stage in which active regions or semiconductor regions 302A, 302B are formed above a substrate 301 and are laterally delineated by an isolation region 302C. It should be appreciated that, for these components, the same criteria may apply as previously described in the context of the semiconductor devices 100 and 200. It should further be appreciated that any components and process strategies described with reference to FIGS. 3a-3h may also be applied or implemented in the device 200, if appropriate.

Furthermore, the device 300 may comprise a thermal oxide layer 303 formed in the semiconductor regions 302A, 302B. In some illustrative embodiments, the thermal oxide material 303 may have been formed at any appropriate manufacturing stage, for instance prior to or after forming the isolation region 302C. The oxide material 303 may have a thickness of one to several nanometers, which may be considered as too thin for acting as a hard mask material during the further processing.

FIG. 3b schematically illustrates the device 300 during a thermal oxidation process 309, in which the thickness of the thermal oxide materials 303 is appropriately increased so as to be compatible with the further processing of the device 300, i.e., for selectively forming a semiconductor material in the semiconductor region 302A. For example, the thickness of the thermal oxide materials 303 may be in the range of 5-10 nm or more, depending on the overall process requirements.

FIG. 3c schematically illustrates the device 300 in a further advanced manufacturing stage. As shown, a resist mask 307 may be provided so as to cover the semiconductor region 302B and a portion of the isolation region 302C, while exposing the semiconductor region 302A and a portion of the isolation region 302C when establishing a gaseous process ambient 305 on the basis of ammonia and gaseous HF. Consequently, as explained above, during the process 305, a sacrificial layer in the form of layer portions 302S formed above exposed areas of the isolation region 302C and a layer portion 303S may be created by initiating a chemical reaction, as is also described above. Furthermore, process conditions during the process 305 may be adjusted so as to obtain a desired reaction rate for the thermal and the deposited oxide materials in view of reducing the overall resulting surface topography, as is also discussed above.

FIG. 3d schematically illustrates the device 300 in a further advanced manufacturing stage, i.e., after the removal of the sacrificial layers 3025, 3035 and after the removal of the resist mask 307. To this end, in some illustrative embodiments, a wet chemical etch process 308 may be applied, for instance on the basis of SPM, while in other cases the layers 302S, 303S may be removed by applying a heat treatment and subsequently removing the resist material 307, wherein the temperature of the heat treatment may be appropriately selected so as to avoid undue modification of the resist mask 307, as is also discussed above. Consequently, the semiconductor region 302A may be exposed without inducing undue surface topography with respect to the isolation structure 302C. On the other hand, the region 302B is still reliably covered by the thermal oxide material 303.

FIG. 3e schematically illustrates the device 300 in a further advanced manufacturing stage in which the device 300 is subjected to a process sequence 312 in order to form a semiconductor material 310, such as a semiconductor alloy for adjusting the electronic characteristics of the active region 302A in compliance with the overall device requirements. To this end, the sequence 312 may comprise an additional cleaning process, for instance based on a wet chemical etch chemistry using diluted hydrofluoric acid, which may efficiently remove any surface contaminations from the active region 302A, which may, however, also remove a certain amount of material of the isolation region 302C and also of the thermal oxide 303, which may, however, have a sufficient thickness so as to act as a reliable hard mask during the further processing. In some illustrative embodiments, the further processing may include a recessing of the active region 302A, as indicated by 311, in order to provide superior surface topography after the selective deposition of the semiconductor material 310. In other cases, as shown in FIG. 3e, the material 310 may be directly deposited on exposed surface areas of the region 302A without forming the recess 311. The material 310 is typically formed on the basis of a selective epitaxial growth process in which process parameters are appropriately selected so as to form a material layer on exposed crystalline surface areas while substantially suppressing a material deposition on dielectric surface areas, such as on the isolation region 302C and on the thermal oxide layer 303. To this end, any well-established process recipes may be applied. For example, the semiconductor material 310 may be formed as a semiconductor alloy so as to adjust the electronic characteristics and thus the threshold voltage of one or more transistors to be formed in and above the semiconductor region 302A, which now includes the layer 310 with an appropriate material composition and layer thickness.

FIG. 3f schematically illustrates the device 300 in a further advanced manufacturing stage. As shown, the thermal oxide 303 may be removed from the semiconductor region 302B, which may be accomplished on the basis of a gaseous process ambient 315 comprising ammonia and hydrogen fluoride, as is also described above. Consequently, during the process 315, a corresponding transformation of oxide material may be initiated, as discussed above. In some illustrative embodiments, a resist mask 317 may be provided so as to cover the material 310 and previously exposed portions of the isolation structure 302C, thereby ensuring superior integrity of the material 310 and also further reducing material loss in the previously exposed portions of the isolation region 302C. In this manner, the previously induced surface topography, which, however, is significantly less compared to conventional strategies, may not be substantially affected by the removal of the thermal oxide 303.

After the process 315, any sacrificial material may be efficiently removed, for instance, by a heat treatment at elevated temperatures, for instance above 200° C., if the resist mask 317 is not provided, while, in other cases, a wet chemical etch process may be applied, as discussed above. In this case, the mask 317 may also be removed, as explained before. In other cases, when the resist mask 317 is used, a heat treatment may be applied with a temperature of 175° C. and less, as is also discussed above. Consequently, undue recessing caused by the removal of the material 303 may be avoided. Hence, the further processing may be continued on the basis of superior surface conditions, thereby enhancing complex lithography and patterning strategies.

FIG. 3g schematically illustrates the device 300 in a further advanced manufacturing stage. As shown, a gate electrode structure 360A may be formed on the semiconductor region 302A, which now includes the semiconductor material 310 as a part thereof, while a second gate electrode structure 360B is formed on the active region 302B, in which the formation of an additional semiconductor material has been blocked by the thermal oxide layer 303 (FIG. 3f).

The gate electrode structures 360A, 360B may, in some illustrative embodiments, comprise a high-k dielectric material 362, which is to be understood as a dielectric material having a dielectric constant of 10.0 and higher. For example, hafnium, zirconium and the like may be provided in the form of oxides and silicates and are appropriate for acting as a gate dielectric material. Frequently, the high-k dielectric material 362 may be provided in combination with a thin conventional dielectric material 361, such as silicon dioxide, silicon oxynitride and the like. Moreover, a metal-containing electrode material 363, for instance in the form of titanium nitride and the like, may be provided in combination with an additional electrode material 364, such as a silicon material, silicon/germanium and the like.

Furthermore, in this manufacturing stage a dielectric cap layer 365 may be provided in the form of a silicon nitride material, a silicon dioxide material or any combination thereof. Typically, the gate electrode structures 360A, 360B may have a gate length, i.e., in FIG. 3g, the horizontal extension of the layer 361, of 50 nm and less, which may thus require complex lithography and patterning strategies, in particular when the sophisticated material system 362, 363 is to be provided, which may have a different material composition for the gate electrode structures 360A, 360B. Consequently, due to the less pronounced surface topography, the patterning of the gate electrode structures 360A, 360B may result in superior uniformity of the cross-sectional shape and thus of the final critical gate length. Furthermore, as previously discussed, typically the sensitive gate materials 362, 363 may require a reliable confinement during the further processing in order to not unduly alter the electronic characteristics of the gate electrode structures 360A, 360B and thus of performance characteristics of the corresponding transistors to be formed. To this end, typically a liner or spacer 366, for instance comprised of silicon nitride and the like, may be formed with appropriate material composition and thickness so as to reliably confine the sidewalls of the materials 362, 363. Since the gate electrode structures 360A, 360B may typically extend into the isolation region 302C in the transistor width direction, i.e., the direction perpendicular to the drawing plane of FIG. 3g, a pronounced topography between the regions 302A, 302B on the one hand and the neighboring portions of the isolation region 302C may also negatively affect the formation of the liner material 366, thereby frequently contributing to pronounced yield losses in conventional strategies. Also in this case, the superior surface topography obtained on the basis of the removal of the thermal oxide, as described, above, may thus provide superior process uniformity.

Basically, the gate electrode structures 360A, 360B may be formed on any appropriate process strategy including the deposition of the materials 361, 362, 363 and possibly the patterning thereof in combination with additional heat treatments for adjusting the work function of the corresponding gate electrode structures 360A, 360B differently if these devices represent different transistor types, followed by the deposition of the materials 364 and 365, which are then patterned by using complex lithography and patterning strategies. Thereafter, the liner material 366 may be deposited and patterned, thereby taking advantage of the superior surface topography, as discussed above.

FIG. 3h schematically illustrates the device 300 in a further advanced manufacturing stage. As shown, a transistor 350A is formed in and above the active region 302A and comprises the gate electrode structure 360A, which may additionally comprise a spacer structure 367. Similarly, a transistor 350B may be formed in and above the active region 302B and may comprise the gate electrode structure 360B, which in turn also includes the spacer structure 367. The transistors 350A, 350B may represent a P-channel transistor and an N-channel transistor, respectively, wherein transistor characteristics are essentially influenced by the gate electrode structures 360A, 360B and, in the transistor 350A, by the material 310. Moreover, appropriate drain and source regions 351 may be formed so as to laterally enclose a channel region, such as a channel region 352A for the transistor 350A, which comprises a portion of the material 310. On the other hand, a channel region 352B of the transistor 350B may have appropriate characteristics without requiring an additional threshold voltage adjusting semiconductor material, as explained above.

The transistors 350A, 350B may be formed on the basis of any appropriate process strategy in which, for instance, the drain and source regions 351 in combination with the spacer structure 367 may be formed by using well-established strategies, for instance incorporating dopant species by implantation techniques and masking regimes and using the spacer structure 367 for defining a lateral offset of the various portions of the drain and source regions 351. Since the lateral and vertical dopant profile of the regions 351 may also essentially influence the finally obtained transistor characteristics, the spacer structure 367 may have to be formed with high precision and uniformity, which also depends on the surface topography of the device 300. Thus, the superior surface topography obtained during the previous processing, irrespective of the provision of the material 310, may thus also result in superior device uniformity. After performing any heat treatments for activating the dopant species and re-crystallizing implantation-induced damage, the further processing may be continued, for instance, by forming metal silicide regions in the drain and source regions 351 and forming a contact level.

It should be appreciated that at any appropriate manufacturing stage the corresponding dielectric cap layers of the gate electrode structures 360A, 360B may be removed in accordance with the overall process requirements.

In still other illustrative embodiments (not shown), the gate electrode structures 360A, 360B may be formed on the basis of conventional gate materials, wherein also the superior surface topography may result in superior uniformity of the resulting gate electrode structures, wherein any sophisticated material systems may be introduced in a later manufacturing stage, for instance, by replacing a portion of the gate electrode structures.

As a result, the present disclosure provides manufacturing techniques in which thermal oxide material, such as silicon dioxide, may be selectively removed in an early manufacturing stage on the basis of a resist mask without requiring any hard mask materials, thereby providing a very efficient process flow while still ensuring superior surface topography since the material loss in isolation regions may be significantly reduced by applying a removal strategy on the basis of a gaseous process ambient including ammonia and gaseous HF.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
providing a thermal oxide layer in a first semiconductor region and a second semiconductor region of a semiconductor device, said first and second semiconductor regions being laterally delineated by an isolation region;
forming a resist mask above said second semiconductor region and a portion of said isolation region so as to expose said thermal oxide layer in said first semiconductor region; and
removing said thermal oxide layer in said first semiconductor region by using a gaseous process ambient comprising ammonia (NH₃) and hydrogen fluoride (HF) and by using said resist mask as a removal mask.

2. The method of claim 1, wherein removing said thermal oxide layer comprises establishing said gaseous process ambient in the presence of said resist mask so as to form a silicon, fluorine, nitrogen and hydrogen comprising sacrificial layer from said thermal oxide layer and removing said sacrificial layer by performing a heat treatment at a process temperature of 175° C. or less.

3. The method of claim 2, wherein performing said heat treatment and establishing said gaseous process ambient are performed in different process environments.

4. The method of claim 1, wherein removing said thermal oxide layer comprises establishing said gaseous process ambient in the presence of said resist mask so as to form a silicon, fluorine, nitrogen and hydrogen comprising sacrificial layer from said thermal oxide layer and commonly removing said sacrificial layer and said etch mask.

5. The method of claim 4, wherein commonly removing said sacrificial layer and said etch mask comprises performing a wet chemical etch process.

6. The method of claim 5, wherein said wet chemical etch process is performed by using a mixture of sulfuric acid and hydrogen peroxide (SPM).

7. The method of claim 1, further comprising forming a first gate electrode structure on said first semiconductor region and a second gate electrode on said second semiconductor region, wherein said first and second gate electrode structures have a gate length of 50 nm or less.

8. The method of claim 7, further comprising forming a semiconductor alloy on said first semiconductor region prior to forming said first and second gate electrode structures.

9. The method of claim 8, wherein forming said semiconductor alloy comprises using said thermal oxide layer on said second semiconductor region as a hard mask.

10. The method of claim 7, wherein forming said first and second gate electrode structures comprises providing a high-k dielectric material above said first and second semiconductor regions.

11. The method of claim 1, further comprising removing said thermal oxide layer from said second semiconductor region by using a second gaseous process ambient that comprises ammonia (NH₃) and hydrogen fluoride (HF).

12. The method of claim 11, wherein removing said thermal oxide layer from said second semiconductor region comprises forming a second resist mask so as to cover said first semiconductor region and establishing said second gaseous process ambient in the presence of said second resist mask.

13. The method of claim 1, wherein providing said thermal oxide layer comprises increasing a thickness of an oxide base layer formed on said first and second semiconductor regions by applying an oxidation process.

14. A method, comprising:
forming a resist mask above a semiconductor device so as to expose a first device region and cover a second device region, at least said first device region comprising a thermal oxide layer;
forming a sacrificial layer from said thermal oxide layer in said first device region by establishing a gaseous process ambient comprising ammonia (NH₃) and hydrogen fluoride (HF) in the presence of said resist mask; and
removing said sacrificial layer and said resist mask by performing a wet chemical etch process.

15. The method of claim 14, wherein said wet chemical etch process is performed on the basis of sulfuric acid and hydrogen peroxide.

16. The method of claim 14, wherein removing said thermal oxide layer is performed so as to expose a semiconductor material in at least a portion of said first device region.

17. The method of claim 16, further comprising forming a semiconductor alloy selectively on said exposed semiconductor material.

18. The method of claim 16, further comprising forming a gate electrode structure on said exposed semiconductor material, wherein said gate electrode structure has a gate length of 50 nm or less and comprises a high-k dielectric material.

19. A method, comprising:
forming a resist mask above a semiconductor device so as to expose a first device region and cover a second device region, at least said first device region comprising a thermal oxide layer;
forming a sacrificial layer from said thermal oxide layer in said first device region by establishing a gaseous process ambient comprising ammonia (NH₃) and hydrogen fluoride (HF) in the presence of said resist mask; and
removing said sacrificial layer in the presence of said resist mask by performing a heat treatment at a temperature of 175° C. or less.

20. The method of claim 19, further comprising removing said resist mask and forming gate electrode structures above said first and second device regions.
